(19) United States
(12) Patent Application Publication
(10) Pub. No.: US 2026/0090402 A1
(43) Pub. Date: Mar. 26, 2026

(54) SEMICONDUCTOR DEVICE AND METHOD OF MANUFACTURING THE SAME

(71) Applicants: Kabushiki Kaisha Toshiba, Kanagawa (JP); Toshiba Electronic Devices & Storage Corporation, Kanagawa (JP)

(72) Inventor: Hiroshi Kadono, Ibo Hyogo (JP)

(21) Appl. No.: 19/312,959

(22) Filed: Aug. 28, 2025

(30) Foreign Application Priority Data
Sep. 20, 2024 (JP) 2024-163660

(51) Int. Cl. H01L 23/495; H01L 21/48; H01L 21/56; H01L 23/00; H01L 23/31

(52) U.S. Cl. CPC H10W 70/424; H10W 70/048; H10W 74/016; H10W 74/114; H10W 70/417; H10W 70/457; H10W 90/736; H10W 90/756

(57) ABSTRACT

According to one embodiment, a semiconductor device includes a semiconductor element provided on a first surface of a lead frame; a package member provided on the lead frame and on the semiconductor element and having a first concave part; and a first terminal provided in the first concave part and extending in a first direction that is parallel to the first surface of the lead frame. The first concave part has a concave shape having a first length in the first direction, a second length in a second direction perpendicular to the first surface of the lead frame, and a third length in a third direction perpendicular to the first direction and the second direction. The third length is shorter than a length of the package member in the third direction.

### CROSS-REFERENCE TO RELATED APPLICATIONS

This application is based upon and claims the benefit of priority from Japanese Patent Application No. 2024-163660, filed Sep. 20, 2024, the entire contents of which are incorporated herein by reference.

### FIELD

Embodiments described herein relate generally to a semiconductor device and a method of manufacturing the same.

### BACKGROUND

A semiconductor device including a lead frame provided with a semiconductor element is known.

### BRIEF DESCRIPTION OF THE DRAWINGS

FIG. 1 is a perspective view of a semiconductor device according to an embodiment when viewed from the top thereof.

FIG. 2 is a perspective view of the semiconductor device according to the embodiment when viewed from the bottom thereof.

FIG. 3 is a top view of the semiconductor device according to the embodiment when viewed through a package member.

FIG. 4 is a cross-sectional view of the semiconductor device according to the embodiment.

FIG. 5 is an enlarged perspective view of a lead terminal and a concave part of the semiconductor device according to the embodiment.

FIG. 6 is a perspective view of a main substrate mounted with the semiconductor device according to the embodiment when viewed from the top thereof.

FIG. 7 is a cross-sectional view of the semiconductor device according to the embodiment which is mounted on the main substrate.

FIG. 8 is an enlarged cross-sectional view of the lead terminal and concave part of the semiconductor device according to the embodiment.

FIG. 9 is a flowchart showing main steps of a method of manufacturing the semiconductor device according to the embodiment.

FIGS. 10 to 18 are diagrams showing the steps of the method of manufacturing the semiconductor device according to the embodiment.

### DETAILED DESCRIPTION

In general, according to one embodiment, a semiconductor device includes a semiconductor element provided on a first surface of a lead frame; a package member provided on the lead frame and on the semiconductor element and having a first concave part; and a first terminal provided in the first concave part and extending in a first direction that is parallel to the first surface of the lead frame. The first concave part has a concave shape having a first length in the first direction, a second length in a second direction perpendicular to the first surface of the lead frame, and a third length in a third direction perpendicular to the first direction and the second direction. The third length is shorter than a length of the package member in the third direction.

According to another embodiment, a method of manufacturing a semiconductor device, includes preparing a lead frame base material including a terminal having a concave shape, and sandwiching the lead frame base material by molds such that a projection guide provided at each of the molds is set in has the concave shape; forming a package member on the lead frame base material, and providing a first concave part having the concave shape in the package member by filling the molds with materials for the package member and curing the materials; and cutting the lead frame base material having the concave shape and the first concave part of the package member by dicing to form a semiconductor device including the terminal having part of the concave shape and the package member having part of the first concave part.

Embodiments will be described below with reference to the drawings. In the following descriptions, the structural elements having the same function and same configuration are denoted by a common reference sign. Each of the embodiments exemplifies a device and a method of embodying the technical concept of the embodiment, and the technical concept does not limit the material, shape, structure, placement, etc. of the structural elements to the following matters.

A semiconductor device and a method of manufacturing the semiconductor device according to an embodiment will be described below.

### 1. Structure of Semiconductor Device

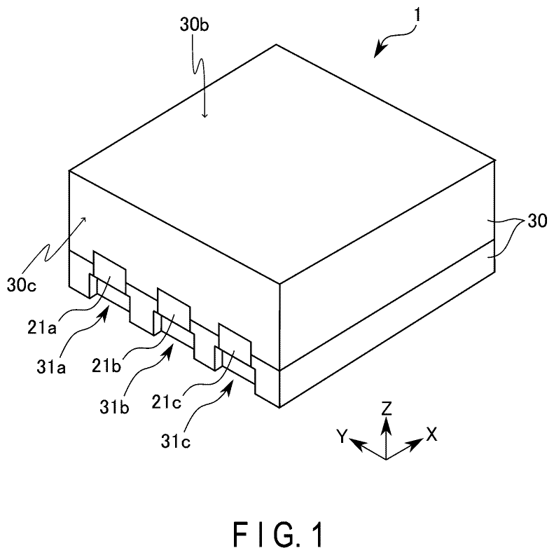

An example of the structure of a semiconductor device 1 according to an embodiment will be described with reference to FIGS. 1 to 4. The semiconductor device 1 includes a semiconductor element, a lead frame and bonding wire, and has a package structure in which they are held or sealed with a package member.

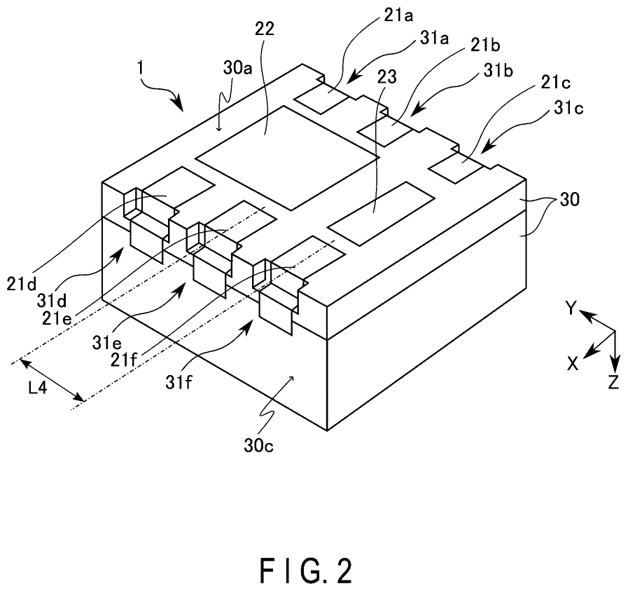

FIGS. 1 and 2 are perspective views each showing an outer shape of the semiconductor device 1. FIG. 1 shows the structure of the semiconductor device 1 when viewed from the top thereof. FIG. 2 shows the structure of the semiconductor device 1 when viewed from the bottom thereof. The bottom of the semiconductor device 1 is a surface from which the terminals of the lead frame are exposed, and is a surface on which the semiconductor device 1 is mounted on a main substrate, or a mounting surface of the semiconductor device 1.

In the following descriptions, an XYZ orthogonal coordinate system is used. The X direction is parallel to the surface of the lead frame and corresponds to a direction in which the lead frame extends. The Y direction corresponds to a direction in which lead terminals are arranged. The Z direction corresponds to a direction perpendicular to the surface of the lead frame, that is, an up and down direction. The “up” and its related terms indicate the positions of larger coordinates on the Z-axis and the “down” and its related terms indicate the positions of smaller coordinates on the Z-axis.

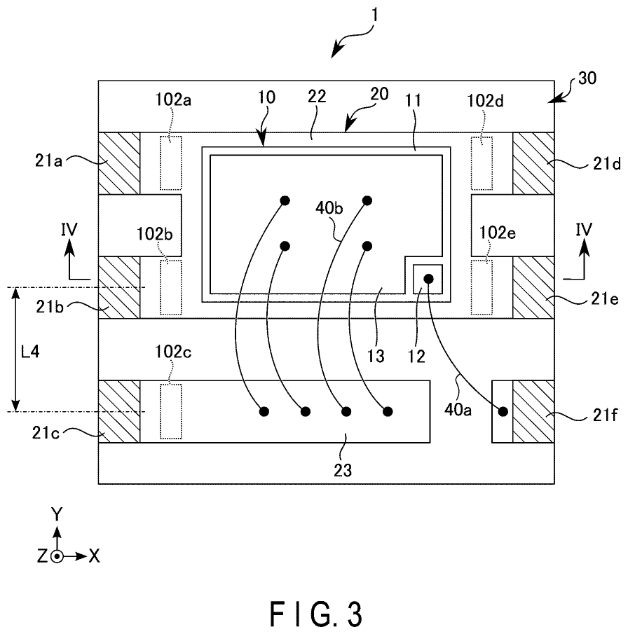

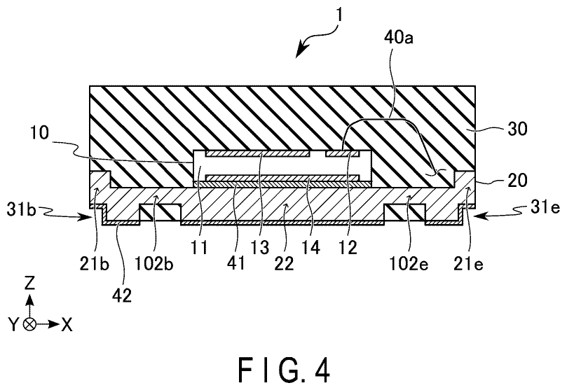

FIG. 3 is a top view of the structure of the semiconductor device 1 according to the embodiment. FIG. 3 shows the structure of the semiconductor device 1 shown in FIG. 1 when viewed through a package member from the top. FIG. 4 is a cross-sectional view of the structure of the semiconductor device 1 according to the embodiment. FIG. 4 shows a cross-sectional structure of the semiconductor device 1 along line IV-IV in FIG. 3.

The semiconductor device 1 includes a semiconductor element 10, a lead frame 20, a package member 30 and bonding wire 40.

As shown in FIGS. 3 and 4, the semiconductor element 10 is provided on the lead frame 20 in the package member 30.

If the semiconductor device 1 is, for example, a discrete device, the semiconductor element 10 is a field effect transistor (e.g., a MOS field effect transistor), a bipolar transistor, an insulated gate bipolar transistor (IGBT) or a diode. As a specific example, the semiconductor element 10 may be a small-signal transistor that controls signal processing or a power transistor (e.g., a high withstand voltage transistor and a high voltage transistor) which controls current and voltage. Hereinafter, a case where the semiconductor element 10 is a field effect transistor will be described as an example.

The semiconductor element 10 is, for example, a semiconductor chip (or a bare chip or a die). The semiconductor element 10 includes an element section 11 and a plurality of pads (or nodes or terminals) 12, 13 and 14.

The element section 11 includes a semiconductor layer on which the field effect transistor is formed. The semiconductor layer is, for example, silicon, silicon carbide, silicon germanium, gallium nitride or gallium arsenide.

The pads 12 and 13 are provided on the upper surface of the element section 11. The pad 12 is connected to the gate of the field effect transistor. The pad 13 is connected to the source of the field effect transistor. Hereinafter, the pad 12 will be referred to as a gate pad 12, and the pad 13 will be referred to as a source pad 13.

The pad 14 is provided on the lower surface of the element section 11. The pad 14 is connected to the drain of the field effect transistor. Hereinafter, the pad 14 will be referred to as a drain pad 14.

Note that the pad 14 may be used as a source pad and the pad 13 may be used as a drain pad depending on the internal configuration of the element section 11. The pads 12, 13 and 14 include a metal layer of aluminum, copper or the like.

The package member (or a sealing member, a resin body, a mold resin or a package resin) 30 is provided on the semiconductor element 10 and the lead frame 20. The package member 30 covers the semiconductor element 10 placed on the lead frame 20 to seal the semiconductor element 10 and the bonding wire 40. The package member 30 is also provided on the upper surface of the lead frame 20 and the lower surface thereof. The package member 30 includes an insulator, such as an insulating resin, ceramics and polyimide.

The lead frame 20 includes a plurality of lead terminals (or outer leads) 21 (including lead terminals 21a, 21b, 21c, 21d, 21e and 21f), a die pad 22, a bonding pad (or an inner lead) 23 and a plurality of connectors 102 (including connectors 102a, 102b, 102c, 102d and 102e). The lead frame 20 includes copper, for example. Hereinafter, the term “lead terminal 21” will refer to each of the lead terminals 21a, 21b, 21c, 21d, 21e and 21f. The term “connector 102” will refer to each of the connectors 102a, 102b, 102c, 102d and 102e.

The lead terminal 21, die pad 22 and bonding pad 23 each have a portion exposed from the package member 30. That is, a portion of each of the lead terminal 21, die pad 22 and bonding pad 23 is exposed from the package member 30 on the lower surface or side surface of the semiconductor device 1. The portion of each of the lead terminal 21, die pad 22 and bonding pad 23, which is exposed from the package member 30, functions as an external connection terminal connected to the outside.

The die pad 22 is adjacent to the bonding pad 23 in the Y direction. The die pad 22 is used as an external connection terminal as described above, and functions as a mount section on which the semiconductor element 10 is mounted.

The semiconductor element 10 is mounted on the upper surface of the die pad 22. The drain pad 14 of the semiconductor element 10 is electrically connected to the die pad 22 via, for example, a conductive member 41 obtained by curing a conductive paste.

The bonding wire 40 (including bonding wire 40a and 40b) electrically connects the semiconductor element 10 with the lead terminal 21f and the bonding pad 23. The bonding wire 40a is bonded between the gate pad 12 of the semiconductor element 10 and the lead terminal 21f. The gate pad 12 is electrically connected to the lead terminal 21f via the bonding wire 40a. The bonding wire 40b is bonded between the source pad 13 of the semiconductor element 10 and the bonding pad 23. The source pad 13 is electrically connected to the bonding pad 23 via the bonding wire 40b.

The lead terminals 21a, 21b and 21c are provided at one end of the semiconductor device 1 in the X direction. The lead terminals 21a and 21b are located at one end of the die pad 22 in the X direction. The lead terminals 21a and 21b are connected to the die pad 22 via the connectors 102a and 102b, respectively.

The lead terminal 21c is located at one end of the bonding pad 23 in the X direction. The lead terminal 21c is connected to the bonding pad 23 via the connector 102c. The lead terminal 21c is electrically insulated from the die pad 22 and the lead terminals 21a, 21b, 21d, 21e and 21f.

The lead terminals 21d, 21e and 21f are provided at the other end of the semiconductor device 1 in the X direction. The lead terminals 21d and 21e are located at the other end of the die pad 22 in the X direction. The lead terminals 21d and 21e are connected to the die pad 22 via the connectors 102d and 102e, respectively.

The lead terminal 21f is located at the other end of the bonding pad 23 in the X direction. The lead terminal 21f is electrically insulated from the die pad 22, the bonding pad 23 and the lead terminals 21a, 21b, 21c, 21d and 21e.

The lead terminals 21a, 21b, 21d and 21e are electrically connected to the drain pad 14 provided on the lower surface of the semiconductor element 10 via the connectors 102a, 102b, 102d and 102e, the die pad 22 and the conductive member 41. The lead terminal 21c is electrically connected to the source pad 13 provided on the upper surface of the semiconductor element 10 via the connector 102c, the bonding pad 23 and the bonding wire 40b. The lead terminal 21f is electrically connected to the gate pad 12 provided on the upper surface of the semiconductor element 10 via the bonding wire 40a.

For example, the portions of the die pad 22, bonding pad 23 and lead terminal 21, which are exposed from the package member 30, are provided with a plating layer 42. Note that the connector 102 is covered with the package member 30 without being exposed from the package member 30.

The die pad 22, bonding pad 23, lead terminal 21 and connector 102 included in the lead frame 20 contain, for example, metal such as copper and aluminum. The plating layer 42 includes, for example, tin or copper.

In the semiconductor device 1 shown in FIGS. 1 to 4, the lead terminal 21 has a Wettable Flank (WF) structure. In the semiconductor device 1 of the embodiment, concave parts (or recess parts) 31a, 31b, 31c, 31d, 31e and 31f are provided in areas where the lead terminals 21a, 21b, 21c, 21d, 21e and 21f are located, respectively. Hereinafter, the concave part 31 will refer to each of the concave parts 31a, 31b, 31c, 31d, 31e and 31f.

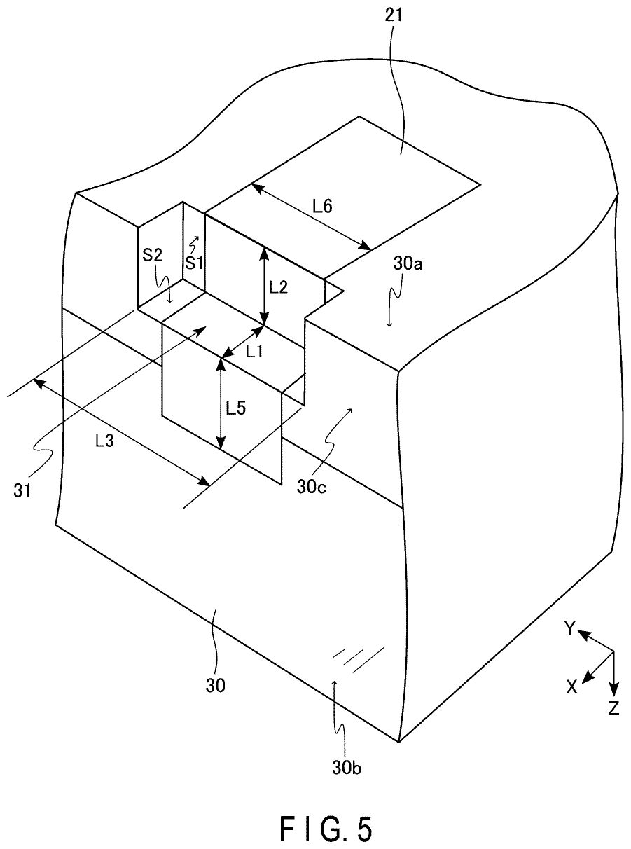

The concave part 31 in the semiconductor device 1 where the lead terminal 21 is located will be described below with reference to FIG. 5. The concave parts 31a, 31b, 31c, 31d, 31e and 31f have similar structures. FIG. 5 is an enlarged view of the concave part 31 in which the lead terminal 21 is located. FIG. 5 is a perspective view of the concave part 31 when viewed from the lower surface 30a of the package member 30.

The concave part 31 is provided in an area of the package member 30 where the lead terminal 21 is located. The package member 30 has a lower surface 30a which is provided on the lower surface of the lead frame 20 opposed to the upper surface of the lead frame 20, an upper surface 30b opposed to the lower surface 30a, and a side surface 30c between the lower surface 30a and the upper surface 30b. The concave part 31 is located at a portion where the lower and side surfaces 30a and 30c of the package member 30 intersect.

The concave part 31 is recessed by distance L1 in the X direction from the side surface 30c of the package member 30 (or semiconductor device 1) and recessed by distance L2 in the Z direction from the lower surface 30a of the package member 30. The length (or width) of the concave part 31 in the Y direction is L3. The length L3 of the concave part 31 in the Y direction is shorter than the length of the package member 30 in the Y direction.

In other words, the concave part 31 of the package member 30 is recessed by length L1 in the X direction, length L2 in the Z direction and length L3 in the Y direction in the area where the lead terminal 21 is located. The concave part 31 is a recess having length L1 in the X direction, length L2 in the Z direction and length L3 in the Y direction at a corner between the lower and side surfaces 30a and 30c of the package member 30.

The lead terminal 21 extends in the X direction along the lower surface 30a of the package member 30, refracts along the inner surface of the concave part 31, that is, along a side surface S1 and a lower surface S2, and is located along the side surface 30c of the package member 30. That is, the lead terminal 21 has a surface along the lower surface 30a of the package member 30, a surface along the side surface S1 in the concave part 31, a surface along the lower surface S2, and a surface along the side surface 30c of the package member 30.

If the length (or the thickness) of the lead terminal 21 exposed in the Z direction from the side surface 30c of the package member 30 is L5 and the length (or the width) of the lead terminal 21 in the Y direction is L6, then L5 is longer than L2 and L2 is longer than L1 (L5>L2>L1). The length L3 of the concave part 31 in the Y direction is longer than the length L6 of the lead terminal 21 in the Y direction (L3>L6).

If, as shown in FIGS. 2 and 3, in the concave parts 31 (or the lead terminals 21) arranged in the Y direction, the distance between the centers of adjacent two concave parts 31 (or lead terminals 21) is L4, then, the length L3 of the concave part 31 in the Y direction is shorter than the distance L4 (L3<L4).

### 2. Example of Mounting of Semiconductor Device

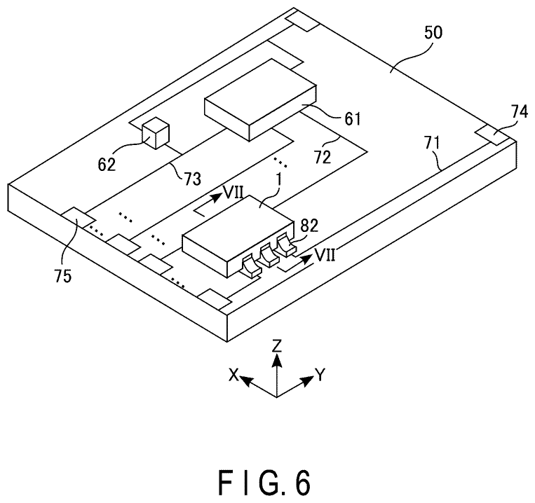

An example in which the semiconductor device 1 of the embodiment is mounted on a main substrate will be described below with reference to FIG. 6. FIG. 6 is a perspective view of the main substrate mounted with the semiconductor device 1 when viewed from the top thereof. The main substrate shown in FIG. 6 may exist as a component or may be located in an electrical device.

The semiconductor device 1 is placed on a surface (hereinafter also referred to as a mounting surface) of the main substrate (or motherboard or printed circuit board) 50. In addition, one or more other devices, such as a semiconductor device 61 and an electronic component 62, are placed on the surface of the main substrate 50.

The main substrate 50 includes a plurality of interconnects 71, 72 and 73 and a plurality of terminals (e.g., connectors, sockets or slots) 74 and 75. The interconnects 71, 72 and 73 are provided on the surface of the main substrate 50 or at the interior of the main substrate 50. Each of the interconnects 71,72 and 73 is connected to one or more terminals corresponding to the terminals 74 and 75 or to at least one of the semiconductor device 1, semiconductor device 61 and electronic component 62 on the main substrate 50. Each of the terminals 74 and 75 is supplied with a corresponding one of various voltages (e.g., power supply voltage VDD and ground voltage GND) or signals.

The semiconductor device 1 is connected to the interconnects 71 and 72 of the main substrate 50. For example, the semiconductor device 1 is connected to the interconnect 74 via the interconnect 71 and to the semiconductor device 61 (or electronic component 62) via the interconnect 72.

The semiconductor device 61 includes a semiconductor integrated circuit, a discrete device, or the like. The semiconductor device 61 may also be a device modularized by a plurality of semiconductor chips and a plurality of passive elements. The electronic component 62 is a passive element, such as a capacitor, an inductor, a resistor and a switch.

The semiconductor device 61 and the electronic component 62 are connected to the terminal 75 via the interconnect 73 or connected to each other via another interconnect.

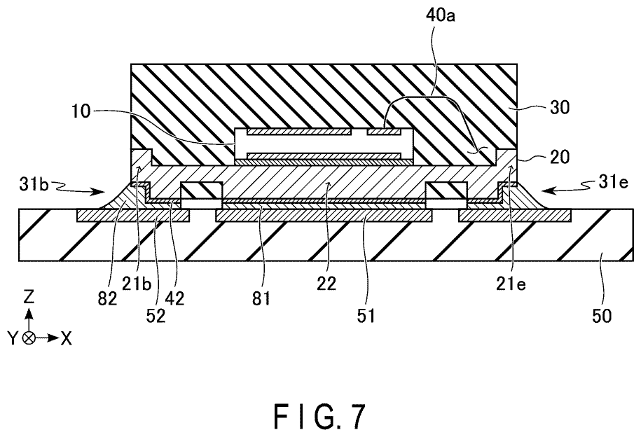

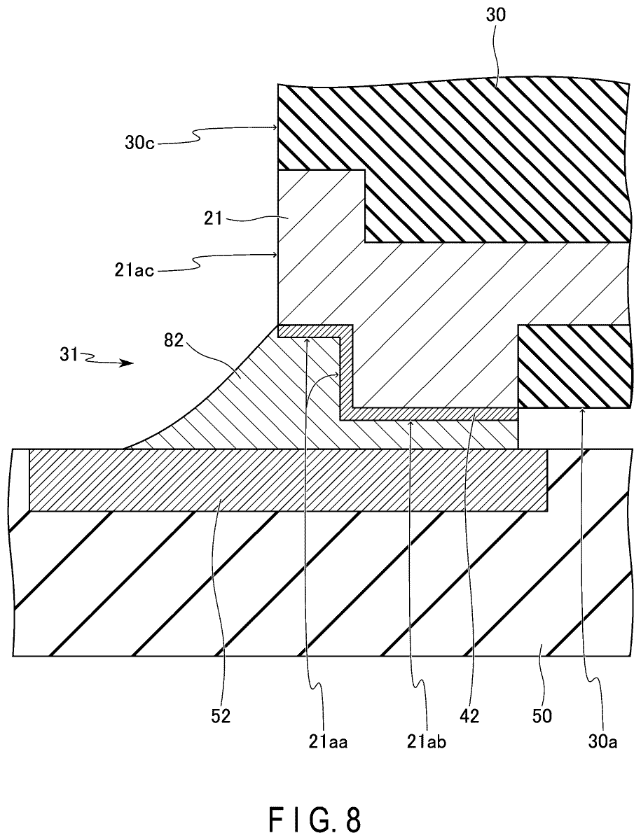

The lead terminal 21 and concave part 31 of the semiconductor device 1 mounted on the main substrate 50 will be described below in detail with reference to FIGS. 7 and 8. FIG. 7 is a cross-sectional view of the semiconductor device 1 mounted on the main substrate 50. FIG. 7 shows a cross section of the semiconductor device 1 along line VII-VII (i.e., XZ plane) in FIG. 6. FIG. 8 is an enlarged view of the lead terminal 21 and concave part 31 shown in FIG. 7. Since the structures of the lead terminal 21a, concave part 31a, lead terminal 21f and concave part 31f are similar, they are referred to as the lead terminal 21 and the concave part 31 in FIG. 8.

As shown in FIG. 7, the die pad 22 of the lead frame 20 is provided on the pad (e.g., interconnect or terminal) 51 of the main substrate 50 via a conductive member 81. Thus, the die pad 22 is electrically connected to the pad 51 of the main substrate 50 via the plating layer 42 and the conductive member 81. The pad 51 is provided on the mounting surface of the main substrate 50. The conductive member 81 includes solder, for example. The pad 51 contains copper, aluminum, or the like.

As shown in FIG. 8, the lead terminal 21 of the semiconductor device 1 is provided on a pad (e.g., interconnect or terminal) 52 of the main substrate 50 via a conductive member 82. The conductive member 82 is provided between the lead terminal 21 and the pad 52. Since the lead terminal 21 has a WF structure, the conductive member 82 is also provided on the lower surface of the lead terminal 21 and on the surface of the lead terminal 21 in the concave part 31. The conductive member 82 is also referred to as a fillet. The fillet 82 is in contact with the lead terminal 21 and the pad 52 to connect the lead terminal 21 and the pad 52 electrically. The conductive member (or fillet) 82 includes, for example, solder. The pad 52 is provided on the mounting surface of the main substrate 50. The pad 52 contains copper, aluminum, or the like.

Specifically, the lead terminal 21 has a terminal face 21aa exposed in the concave part 31, a terminal face 21ab exposed in the lower surface 30a of the package member 30, and a terminal face 21ac exposed in the side surface 30c of the package member 30. In other words, the surface of the lead terminal 21 is located along the lower surface 30a of the package member 30, the inner surface in the concave part 31 and the side surface 30c of the package member 30. The terminal faces 21aa and 21ab of the lead terminal 21 are electrically connected to the pads 52 of the main substrate 50 via the plating layer 42 and the fillet 82. Note that the terminal face 21ac of the lead terminal 21 is a surface exposed after cutting a lead frame base material 120 by dicing, as will be described later. Thus, no plating layer is provided on the terminal face 21ac, but an oxide layer (not shown) is formed. In many cases, therefore, no fillet is provided on the terminal face 21ac of the lead terminal 21.

The semiconductor device 1 of the embodiment described above includes the concave part 31 on the side surface of the package member 30 and the lead terminal 21 located along the inner surface (or side and lower surfaces) of the concave part 31. When the semiconductor device 1 so configured is mounted on the main substrate 50, the fillet 82 enters the concave part 31 to connect the lead terminal 21 and the pad 52 electrically.

Since the fillet 82 is formed to enter the concave part 31, it can be formed to have a predetermined shape and size. It is thus possible to improve the mounting strength due to the fillets 82 formed in a plurality of concave parts 31 of the semiconductor device 1 and to reduce variations in the mounting strength, and to stabilize electrical connection between the lead terminal 21 and the pad 52. Therefore, the semiconductor device 1 can be improved in its mounting reliability.

### 3. Method of Manufacturing Semiconductor Device

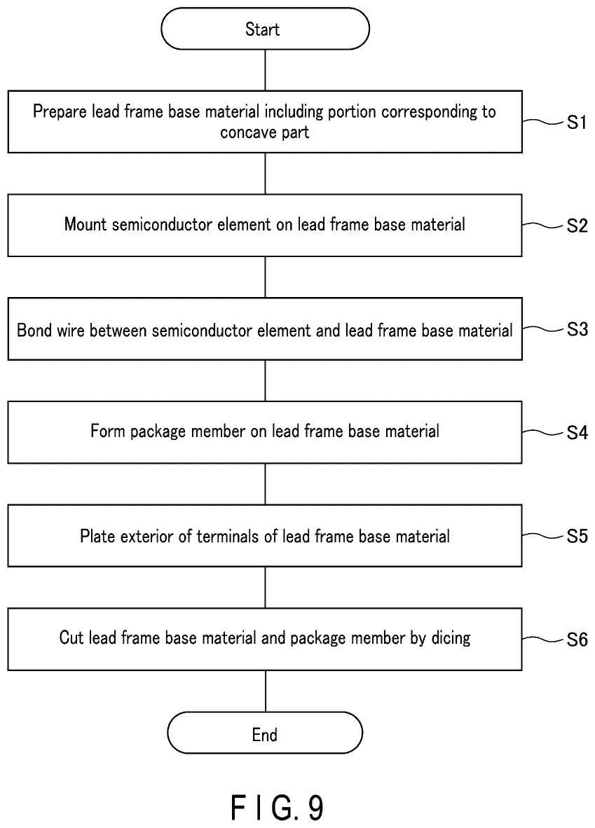

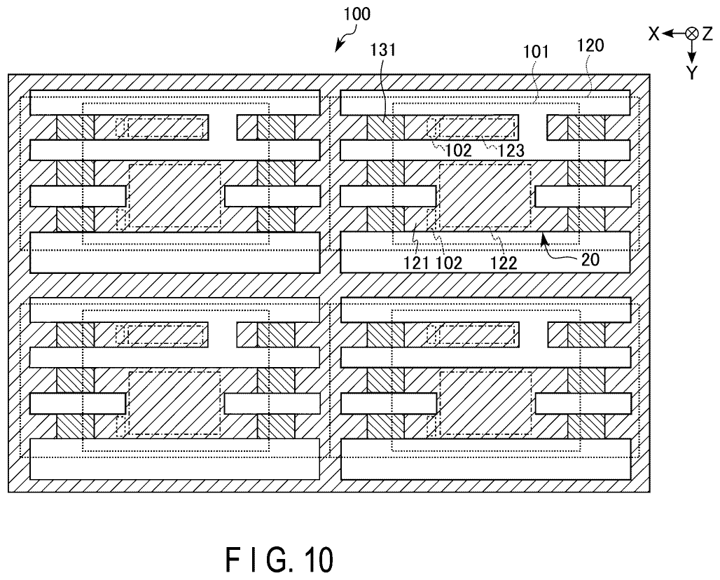

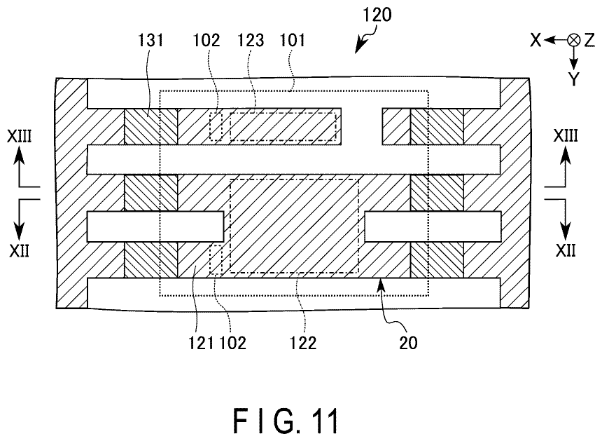

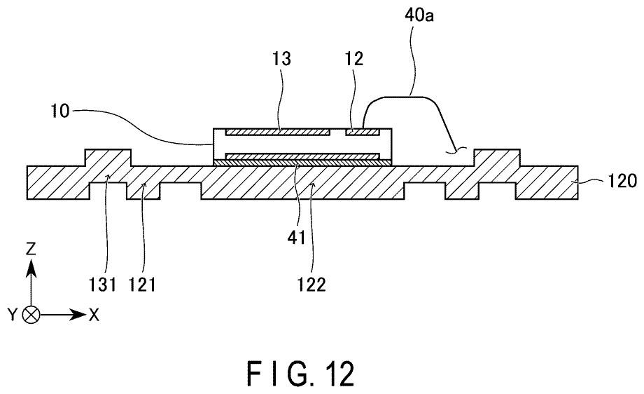

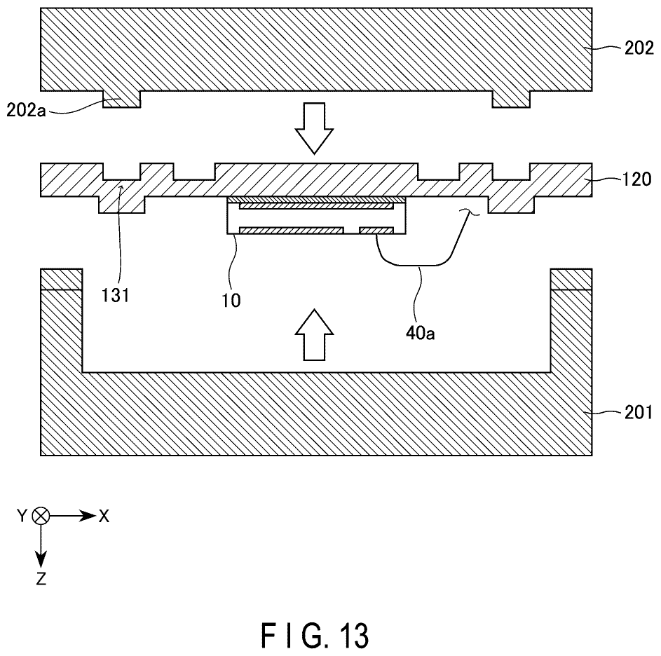

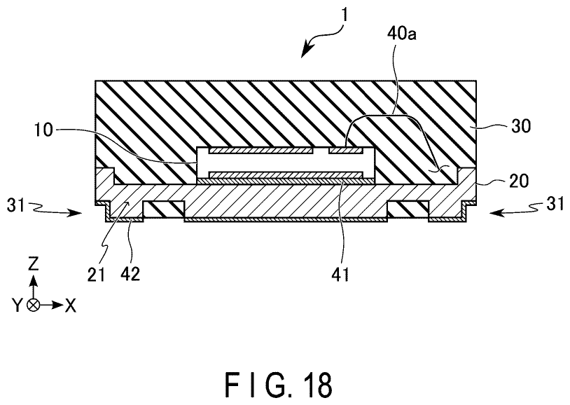

A method of manufacturing the semiconductor device 1 according to the embodiment will be described below with reference to FIGS. 9 to 18. FIG. 9 is a flowchart showing main steps in the method of manufacturing the semiconductor device 1. FIGS. 10 to 18 are diagrams showing the steps in the method of manufacturing the semiconductor device 1. FIGS. 10 and 11 are plan views of the lead frame base material when viewed from the bottom thereof. FIGS. 12 and 18 are cross-sectional views of the semiconductor element 10 taken along line XII-XII in FIG. 11 with the top of the semiconductor element 10 facing upward. FIGS. 13 to 17 are cross-sectional views of the semiconductor element 10 taken along line XIII-XIII in FIG. 11, with the bottom of the semiconductor element 10 facing upward.

First, as shown in FIG. 10, a lead frame base material 100 including a terminal having a portion (or a concave shape) 131 corresponding to the concave part 31 is prepared (step S1). The lead frame base material 100 is formed by connecting a plurality of lead frames 20 corresponding to a plurality of semiconductor devices 1. In an area 101 of the lead frame base material 100 which corresponds to one of the semiconductor devices 1, there are a portion 131 corresponding to the concave part 31, a portion 121 corresponding to the lead terminal 21, a portion 122 corresponding to the die pad 22, a portion 123 corresponding to the bonding pad 23, a connector 102 connecting the die pad 22 and the lead terminal 21, and a connector 102 connecting the bonding pad 23 and the lead terminal 21.

The portion 131 corresponding to the concave part 31 of the lead frame base material 100 has a shape recessed in the Z direction. The portion 131 is formed, for example, by punching using a mold (or press working). The lead frame base material 100 contains, for example, copper (or aluminum).

Hereinafter, in order to simplify the drawings, the manufacturing method will be described using the lead frame base material 120 including the area 101 corresponding to one semiconductor device 1, as shown in FIG. 11.

As shown in FIG. 12, a semiconductor element 10 is mounted on the lead frame base material 120 with a conductive member 41 therebetween (step S2). Then, bonding wire 40a is bonded between the gate pad 12 of the semiconductor element 10 and the portion 121 corresponding to the lead terminal. In addition, bonding wire 40b is bonded between the source pad 13 of the semiconductor element 10 and the portion 123 corresponding to the bonding pad (not shown) (step S3). Thus, the gate pad 12 of the semiconductor element 10 and the portion 121 corresponding to the lead terminal are electrically connected via the bonding wire 40a. In addition, the source pad 13 of the semiconductor element 10 and the portion 123 corresponding to the bonding pad are electrically connected via the bonding wire 40b.

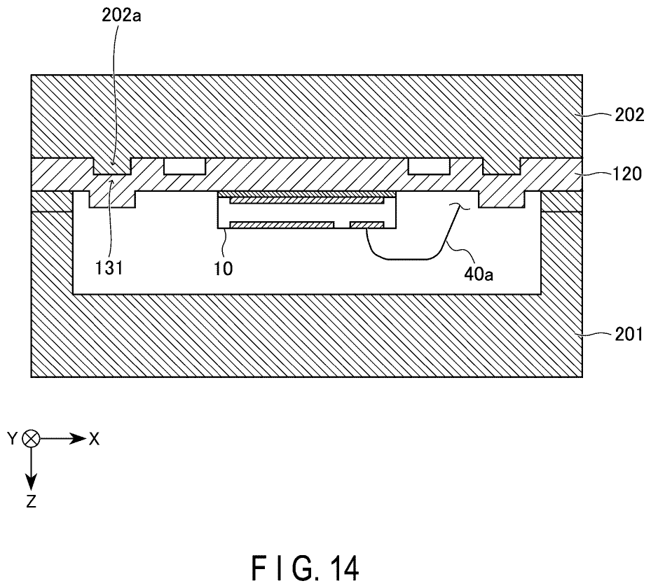

As shown in FIGS. 13, 14 and 15, a package member 30 is formed on part of the lower and upper surfaces of the lead frame base material 120 provided with the semiconductor element 10 and the bonding wires 40a and 40b (step S4). Specifically, as shown in FIGS. 13 and 14, first, the lead frame base material 120 is sandwiched between a lower mold 201 and an upper mold 202. At this time, a projection guide 202a of the upper mold 202 is located in the portion 131 corresponding to the concave part 31 of the lead frame base material 120. Then, the space between the lower and upper molds 201 and 202, that is, the space between the lower mold 201 and the upper surface of the lead frame base material 120 and the space between the upper mold 202 and the lower surface of the lead frame base material 120 are filled with resin.

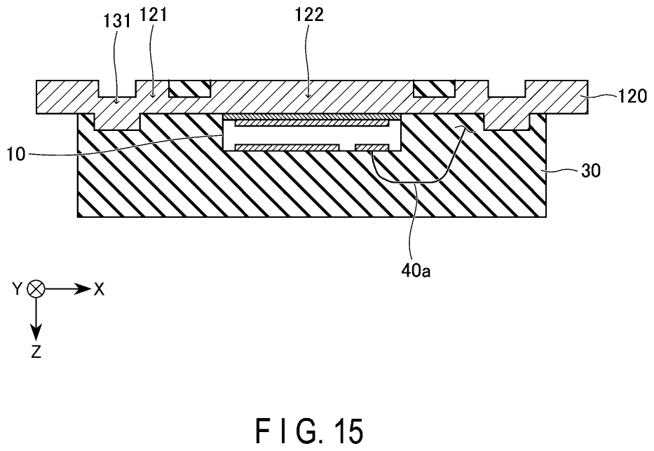

As a result, as shown in FIG. 15, the package member 30 is formed on the upper surface of the lead frame base material 120, on the semiconductor element 10, and on part of the lower surface of the lead frame base material 120. At this time, a concave part including the portion 131 is provided in the package member 30. The semiconductor element 10 and bonding wires 40a and 40b on the lead frame base material 120 are sealed by the package member 30.

In the lead frame base material 120, the surface of each of the portion 131 corresponding to the concave part 31, the portion 121 corresponding to the lead terminal 21, the portion 122 corresponding to the die pad 22 and the portion 123 corresponding to the bonding pad 23 is exposed from the package member 30. In the step of forming the package member 30, a thin burr, which is a material of the package member, is formed on the side surface of the portion 131 corresponding to the concave part 31, and the thin burr is removed through, for example, a laser irradiation process and a honing process.

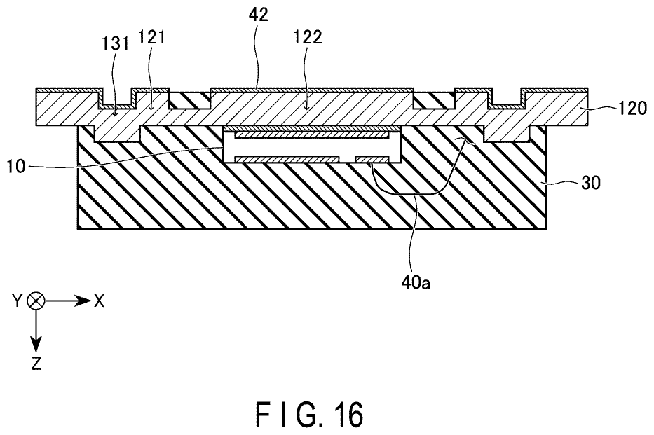

Then, as shown in FIG. 16, the portions 131, 121, 122 and 123 of the lead frame base material 120 exposed from the package member 30 are exterior-plated (step S5). Specifically, a plating layer 42 is formed on the portion 131 corresponding to the concave part 31, the portion 121 corresponding to the lead terminal 21, the portion 122 corresponding to the die pad 22 and the portion 123 corresponding to the bonding pad 23, which are exposed from the package member 30 by electrolytic plating, for example. The plating layer 42 contains tin, solder, or the like.

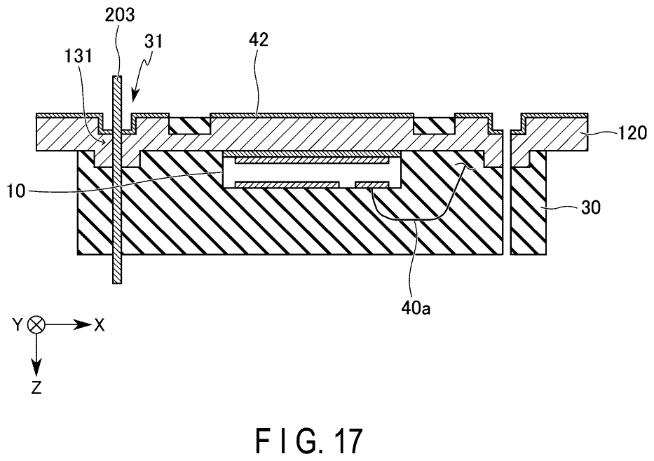

After that, as shown in FIG. 17, the lead frame base material 120 and the package member 30 are fully cut by dicing. Thus, the lead frame base material 120 is cut into chips to obtain a semiconductor device 1 as shown in FIG. 18 (step S6). Specifically, the central part of the portion 131 of the lead frame base material 120 and the central part of the portion corresponding to the concave part 31 of the package member 30 are cut using a dicing blade 203. Thus, a semiconductor device 1 including a lead terminal 21 having part of the portion 131 and a package member 30 having a concave part 31 is formed. The process of manufacturing the semiconductor device 1 is therefore ended.

Then, as shown in FIG. 6, the semiconductor device 1 is mounted on the main substrate 50 by the reflow process, for example. A fillet 82 is formed on the side surface of the semiconductor device 1. The fillet 82 fixes the semiconductor device 1 on the main substrate 50 and electrically connects the lead terminal 21 of the semiconductor device 1 and the pad 52 of the main substrate 50.

After that, various inspections, such as automated optical inspection (AOI), are conducted on the semiconductor device 1 on the main substrate 50 using a test device. For example, the shape of the fillet 82 formed at the lead terminal 21 is inspected by the AOI. It is thus determined whether or not the semiconductor device 1 and the main substrate 50 are in a good bonding state.

After the inspections, devices including the main substrate 50 on which the semiconductor device 1 of the embodiment is mounted or including the semiconductor device 1 of the embodiment are shipped to the market or users.

As described above, in the embodiment, a central part of the portion 131 corresponding to the concave part 31 provided in the lead frame base material 120 is cut by the dicing blade 203. Thus, the side of the lead terminal 21 in the concave part 31 is hardly affected by a failure caused by wear or the like of the dicing blade 203. Therefore, when the semiconductor device 1 is mounted, the shape of the fillet 82 formed in the lead terminal 21 in the concave part 31 can be stabilized.

In addition, when the semiconductor device 1 is mounted, the conductive member serving as the fillet 82 enters the concave part 31 provided on the side of the package member 30; thus, the fillet 82 can be formed to have a stable shape and size.

As described above, when the semiconductor device 1 is mounted on the main substrate 50, the fillet 82 can improve the mounting strength and reduce variations in the mounting strength, with the result that the electrical connection between the lead terminal 21 and the pad 52 can be stabilized. Accordingly, the semiconductor device 1 can be improved in the reliability of the mounting.

In the embodiment, the shape and size of the fillet 82 formed in the lead terminal 21 can be stabilized as described above. Thus, the mounting state of the semiconductor device 1 can easily be inspected by AOI, and the accuracy of the inspection can be improved. Therefore, the main substrate 50 or equipment including the semiconductor device 1 of the embodiment can be improved in quality reliability.

In addition, when the lead frame base material and the package member are cut by dicing, exfoliation may occur between them. In the semiconductor device 1 of the embodiment, since a lead terminal is protruded in the Z direction toward the portion 131 corresponding to the concave part 31 from the cut surface at the time of the dicing, that is, the lead terminal 21 provided at the portion 131 corresponding to the concaved part 31 is shaped like a protrusion, the stress caused at the time of dicing is relaxed by the protruded lead terminal. It is thus possible to reduce exfoliation occurring between the lead terminal 21 and the package member 30. Therefore, the semiconductor device 1 can be prevented from decreasing in moisture resistance and can be improved in reliability.

As has described above, according to the semiconductor device 1 of the embodiment and its manufacturing method, the semiconductor device 1 can be improved in its mounting on the main substrate and furthermore can be improved in its reliability.

### 4. Others

The foregoing embodiment is directed to an example in which the semiconductor device 1 is a field-effect transistor. However, the semiconductor device 1 may be a semiconductor integrated circuit, an image sensor, an optical device, or a memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor element provided on a first surface of a lead frame;
a package member provided on the lead frame and on the semiconductor element and having a first concave part; and
a first terminal provided in the first concave part and extending in a first direction that is parallel to the first surface of the lead frame,
wherein:
the first concave part has a concave shape having a first length in the first direction, a second length in a second direction perpendicular to the first surface of the lead frame, and a third length in a third direction perpendicular to the first direction and the second direction; and
the third length is shorter than a length of the package member in the third direction.

2. The semiconductor device according to claim 1,
wherein:
the package member has a lower surface alongside a second surface opposed to the first surface of the lead frame, an upper surface opposed to the lower surface, and a side surface between the lower surface and the upper surface; and
the first concave part is located at a portion where the lower surface and the side surface of the package member intersect.

3. The semiconductor device according to claim 1, further complicating a second terminal extending in the first direction,
wherein:
the package member includes a second concave part located adjacent to the first concave part in the third direction;
the second terminal is provided in the second concave part; and
if the first length of the first concave part is L1, the second length thereof is L2, the third length thereof is L3, and an interval between a central part of the first concave part and a central part of the second concave part is L4, L4>L3>L2>L1.

4. The semiconductor device according to claim 1,
wherein the first terminal is located so as to be refracted along an inner surface of the first concave part.

5. The semiconductor device according to claim 1,
wherein:
the package member has a lower surface alongside a second surface opposed to the first surface of the lead frame, an upper surface opposed to the lower surface, and a side surface between the lower surface and the upper surface;
the first terminal has a first terminal face exposed from an inner surface of the first concave part and a second terminal face exposed from the side surface of the package member; and
a length of the second terminal face in the second direction is longer than a length of the first terminal face in the second direction, and the length of the first terminal face in the second direction is longer than a length of the first terminal face in the first direction.

6. The semiconductor device according to claim 1,
wherein:
the package member has a lower surface alongside a second surface opposed to the first surface of the lead frame, an upper surface opposed to the lower surface, and a side surface between the lower surface and the upper surface; and
the first terminal has a first terminal face exposed from an inner surface of the first concave part and a second terminal face exposed from the lower surface of the package member.

7. The semiconductor device according to claim 6,
wherein the first terminal includes a plating layer on the first terminal face and the second terminal face.

8. The semiconductor device according to claim 1, further comprising wire connecting the semiconductor element and the first terminal.

9. A method of manufacturing a semiconductor device, comprising:
preparing a lead frame base material including a terminal having a concave shape, and sandwiching the lead frame base material by molds such that a projection guide provided at each of the molds is set in has the concave shape;
forming a package member on the lead frame base material, and providing a first concave part having the concave shape in the package member by filling the molds with materials for the package member and curing the materials; and
cutting the lead frame base material having the concave shape and the first concave part of the package member by dicing to form a semiconductor device including the terminal having part of the concave shape and the package member having part of the first concave part.

10. The method of manufacturing the semiconductor device according to claim 9 further comprising forming the lead frame base material to have the concave shape before the package member is formed.

11. The method of manufacturing the semiconductor device according to claim 9 further comprising forming the package member and then forming a plating layer on the terminal and the concave shape exposed from the package member before the dicing.

12. The method of manufacturing the semiconductor device according to claim 9 further comprising:
mounting a semiconductor element on the lead frame base material before forming the package member; and
bonding wire between the semiconductor element and the terminal of the lead frame base material.

13. The method of manufacturing the semiconductor device according to claim 9, wherein the semiconductor device includes:
a semiconductor element provided on a first surface of a lead frame;
a package member provided on the lead frame and on the semiconductor element and having a first concave part; and
a first terminal provided in the first concave part and extending in a first direction that is parallel to the first surface of the lead frame,
wherein:
the first concave part has a concave shape having a first length in the first direction, a second length in a second direction perpendicular to the first surface of the lead frame, and a third length in a third direction perpendicular to the first direction and the second direction; and
the third length is shorter than a length of the package member in the third direction.

14. The method of manufacturing the semiconductor device according to claim 13,
wherein:
the package member has a lower surface alongside a second surface opposed to the first surface of the lead frame, an upper surface opposed to the lower surface, and a side surface between the lower surface and the upper surface; and
the first concave part is located at a portion where the lower surface and the side surface of the package member intersect.

15. The method of manufacturing the semiconductor device according to claim 13,
wherein:
the semiconductor device includes a second terminal extending in the first direction;
the package member includes a second concave part located adjacent to the first concave part in the third direction;
the second terminal is provided in the second concave part; and
if the first length of the first concave part is L1, the second length thereof is L2, the third length thereof is L3, and an interval between a central part of the first concave part and a central part of the second concave part is L4, L4>L3>L2>L1.
